(19) United States
(12) Patent Application Publication
(10) Pub. No.: US 2012/0224307 A1
(43) Pub. Date: Sep. 6, 2012

(54) DAMPING DEVICE FOR TRANSVERSE SLIDING-TYPE PORTABLE TERMINAL

(75) Inventors: Hyun-Suk SHIN, Gyeonggi-do (KR); Jeong-Hun SEO, Gyeonggi-do (KR)

(73) Assignee: SAMSUNG ELECTRONICS CO., LTD., Gyeonggi-Do (KR)

(21) Appl. No.: 13/351,332

(22) Filed: Jan. 17, 2012

(30) Foreign Application Priority Data
Mar. 2, 2011 (KR) 10-2011-0018349

(51) Int. Cl. H05K 7/00

(52) U.S. Cl. 361/679.01

(57) ABSTRACT

The present disclosure provides a damping device for a transverse sliding-type portable terminal includes a body, a sliding body, a sliding guide module configured to transversely guide the sliding of the sliding body on the body, wherein the damping device is installed at a central portion of a front circumference of the sliding body to minimize friction during an opening/closing operation of the sliding body with respect to the body.

### CLAIM OF PRIORITY

This application claims priority under 35 U.S.C. §119 to a Korean Patent Application entitled “Damping Device For Transverse Sliding-Type Portable Terminal” filed in the Korean Intellectual Property Office on Mar. 2, 2011 and assigned Serial No. 10-2011-0018349, the contents of which are incorporated herein by reference.

### BACKGROUND OF THE INVENTION

1. Field of the Invention

The present invention relates to a sliding-type portable terminal, and more particularly to a damping device adapted to minimize friction during an opening/closing operation of a transverse sliding-type portable terminal

2. Description of the Related Art

In general, a portable terminal refers to a portable electronic device such as a cellular phone, a smart phone, a tablet PC, and a PDA.

Such portable terminals are classified into a bar type, a folder type, and a sliding type according to their appearances. A bar-type portable terminal refers to a portable terminal having a bar type body in which a data input unit and a data output unit are mounted. A folder-type portable terminal includes a body, a folder, and a hinge rotatably connecting the folder to the body, where a data input unit is installed in the body and a data output unit is installed in the folder. A sliding-type portable terminal includes a body, a sliding body, and a sliding module connecting the sliding body to the body, where a data input unit is installed in the body and a data output is installed in the slider. A keypad or a touch screen may be installed as a data input unit employed in the above-listed type portable terminals. An LCD or an AMOLED may be used as a data output unit.

Sliding-type portable terminals are classified into a longitudinal sliding-type potable terminal and a transverse sliding-type portable terminal. The longitudinal sliding-type portable terminal refers to a portable terminal adapted to open and close a predetermined region of a top surface of a body while a sliding body is slid in a lengthwise direction of the body. The transverse sliding-type portable terminal refers to a portable terminal adapted to open and close a predetermined region of a top surface of a body while a sliding body is slid in a direction perpendicular to a lengthwise direction of the body.

The transverse sliding-type portable terminal typically includes a body and a sliding body configured to be slid in a direction perpendicular to a lengthwise direction of the body, and a sliding guide module connects the body and the sliding body. A keypad having a QWERTY arrangement may be installed on a top surface of the body, and a display such as an LCD or a touch screen such as a touch sensitive panel is installed on a top surface of the sliding body. The siding body is slid on a top surface of the body to open and close the keypad. Since a body and a sliding body are stacked from top to bottom and a sliding module is mounted between them, the portable terminal tends to be thicker than other terminal types. Thus, it is necessary to slim the portable terminal for a user to conveniently carry and use it. To achieve this,

the transverse sliding-type portable terminal has been slimmed by sliming a body or a sliding body.

However, a slimmed transverse sliding-type portable terminal causes a scratch due to friction during an opening/closing operation thereof That is, a deflection occurs at a central portion of a front side of a transverse sliding-type portable terminal, often causing scratches due to direct friction between an injection-molded body housing and an injection-molded sliding body housing. In particular, scratches caused during an opening/closing operation of a transverse sliding-type portable terminal are concentrated at central portions of front sides of the housings.

According, there is a need to minimize the scratch and friction at a central portion of a front side of a transverse sliding-type portable terminal

### SUMMARY OF THE INVENTION

Accordingly, the present invention has been made to solve the above-mentioned problems occurring in the prior art and provides additional advantages, by providing a damping device for a transverse sliding-type portable terminal which minimizes scratches occurring during an opening/closing operation thereof by providing a wear-resistant damper at a location where friction occurs most frequently.

Another aspect of the present invention provides a damping device for a transverse sliding-type portable terminal which is mounted to a portion of the transverse sliding-type portable terminal where it cannot be seen from the outside to make an appearance of the transverse sliding-type portable terminal more appealing.

A further aspect of the present invention provides a damping device for a transverse sliding-type portable terminal one surface of which can be detachably mounted.

In accordance with an aspect of the present invention, a damping device for a transverse sliding-type portable terminal includes a body, a sliding body, a sliding guide module configured to transversely guide the sliding of the sliding body on the body, wherein the damping device is installed at a central portion of a front circumference of the sliding body to minimize friction during an opening/closing operation of the sliding body with respect to the body.

### BRIEF DESCRIPTION OF THE DRAWINGS

The above and other aspects, features and advantages of the present invention will be more apparent from the following detailed description taken in conjunction with the accompanying drawings, in which:

FIG. 1 is a perspective view illustrating a transverse sliding-type portable terminal in a closed state;

FIG. 2 is a perspective view illustrating a transverse sliding-type portable terminal in an opened state;

FIG. 3 is a side view illustrating a transverse sliding-type portable terminal in a closed state;

FIG. 4 is a perspective view illustrating a damping device mounted to a transverse sliding-type portable terminal according to an embodiment of the present invention;

FIG. 5 is a partially cutaway perspective view illustrating a damping device mounted to a transverse sliding-type portable terminal according to the embodiment of the present invention; and

FIG. 6 is a sectional view illustrating a damping device mounted to a transverse sliding-type portable terminal according to the embodiment of the present invention.

### DETAILED DESCRIPTION OF THE PRESENT INVENTION

Hereinafter, a damping device employed in a transverse sliding-type according to an embodiment of the present invention will be described with reference to the accompanying drawings. The same or similar reference numerals in the drawings indicate the same or similar elements.

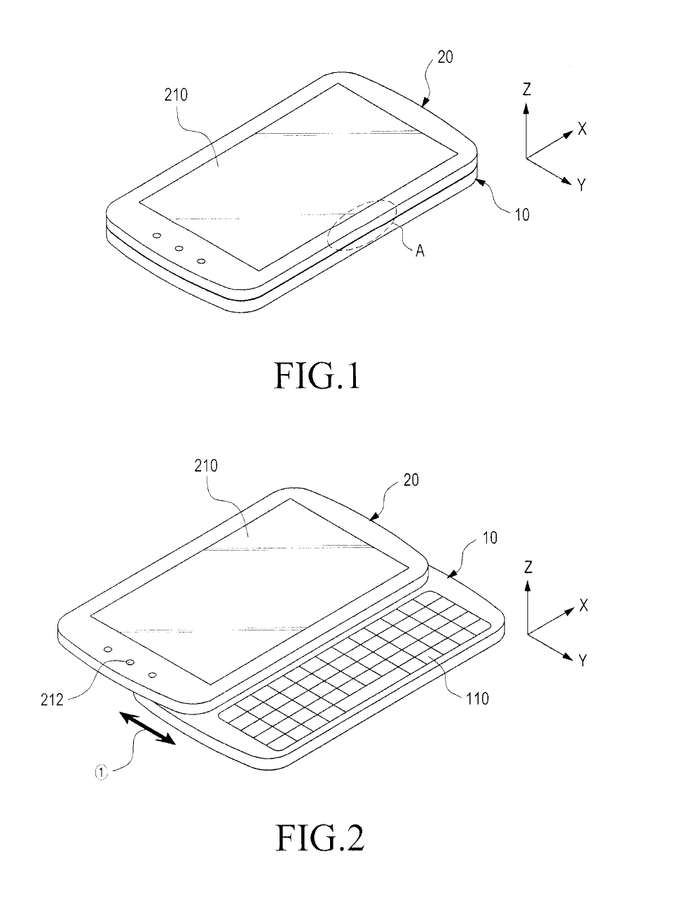

FIG. 1 is a perspective view illustrating a transverse sliding-type portable terminal in a closed state, and FIG. 2 is a perspective view illustrating a transverse sliding-type portable terminal in an opened state.

In the disclosure, the term “transverse” refers to a direction perpendicular to a lengthwise direction of a body 10 and a sliding body 20, and the term “longitudinal” refers to a lengthwise direction (the X-axis direction) of the body 10 and the sliding body 20.

The X-axis direction refers to a lengthwise direction of the sliding body 20, the Y-axis direction, to a perpendicular (transverse) direction, and the Z-axis direction, to a 25 vertical direction of the body 10 and the sliding body 20. That is, the X axis refers to a rightward/leftward direction (a side direction), the Y-axis direction, to a forward/rearward direction (a sliding direction; the +Y-axis refers to a forward direction and the -Y-axis refers to a rearward direction), and the Z-axis direction, to an upward/downward direction.

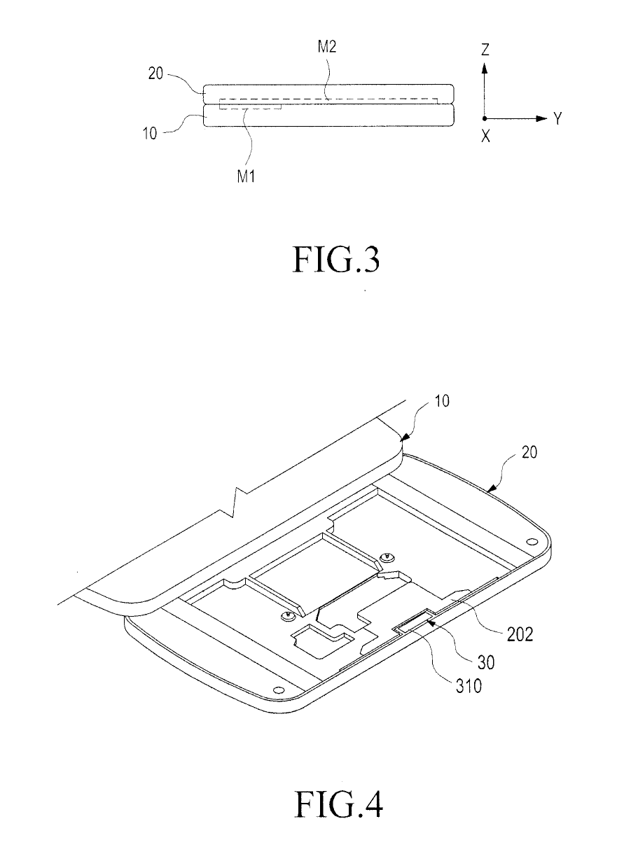

The transverse sliding-type portable terminal according to the embodiment of the present invention includes a body 10, a sliding body 20, and a sliding guide module (see FIG. 3) connecting the sliding body 20 to the body 10. The sliding body 20 having a display mounted thereon moves in a direction of an arrow 1 to open and close an upper surface of the body 10. A QWERTY key may be disposed in the body 10 of the transverse sliding-type portable terminal, making it easy for a user to input data with one or two hands.

A key pad 110 including a QWERTY key arrangement is installed on a top surface of the body 10, and a key 212 and a display 210 are disposed on a top surface of the sliding body 20.

Referring to FIG. 3, the sliding guide module M1 and M2 is mounted between the body 10 and the sliding body 20, and serves to connect the sliding body 20 to a top surface of the body 10, guide the sliding body 20 on the body 20, and open and close the sliding body 20 manually, automatically, or semi-automatically. The first and second sliding guide modules M1 and M2 are interlockingly coupled to each other such that the sliding body 20 is guided on the body 10. That is, the sliding body 20 is slid transversely (in a Y-axis direction) on the body 10 by the first and second sliding guide modules M1 and M2 to open and close a keypad on a top surface of the body 10.

To minimize the friction when the sliding body 20 is opened and closed with respect to the body 10, a damping device 30 (see FIG. 4) and a damper 310 (see FIG. 4) are installed in a specific region A to minimize the friction when the sliding body 20 is slid transversely during an opening/closing operation thereof. Thus, the damping device 30 serves to smooth the opening/closing operation of the transverse sliding-type portable terminal.

Referring to FIGS. 1 and 4, the damping device 30 is preferably installed at a point A where friction is severe during an opening/closing operation of the body 10 or the sliding body 20. The damping device 30 is preferably installed in the sliding body 20, and more preferably at a center portion of the front circumference of the sliding body 20.

In operation, a user selectively opens and closes the sliding body 20 to use the transverse sliding-type portable terminal, in which case the sliding body 20 is slightly pushed to be opened and closed. In particular, a central region of the sliding body 20 is slightly pushed transversely. Then, deflections occur more frequently at a central portion of the sliding body 20 and at opposite sides of the sliding body 20 as a user generally pushes the sliding body 20 transversely after slightly pushing it toward a front side. Thus, the damping device 30 is mounted to the sliding body 20 to address the most frictional region which occurs during an opening/closing operation of the sliding body 20.

Moreover, friction occurring during an opening/closing operation of the transverse sliding-type portable terminal is generally caused by direct contact between a central portion of a front circumference of the body 10 and a central portion of a front circumference of the sliding body 20. Thus, the damping device 30 may be mounted to a bottom surface of the sliding body 30 at a central portion of a front circumference of the sliding body 20, considering an external design of the transverse sliding-type portable terminal. More preferably, the damping device 30 is mounted to a bottom surface of the sliding body 20 at a central portion of a front circumference thereof toward the inside (rear side) thereof. Hence, the mounting position of the damping device 30 cannot be seen by a user. That is, since the damping device 30 according to the embodiment of the present invention is hidden within the transverse sliding-type portable terminal, it is not exposed to the outside irrespective of an opened/closed state of the transverse sliding-type portable terminal.

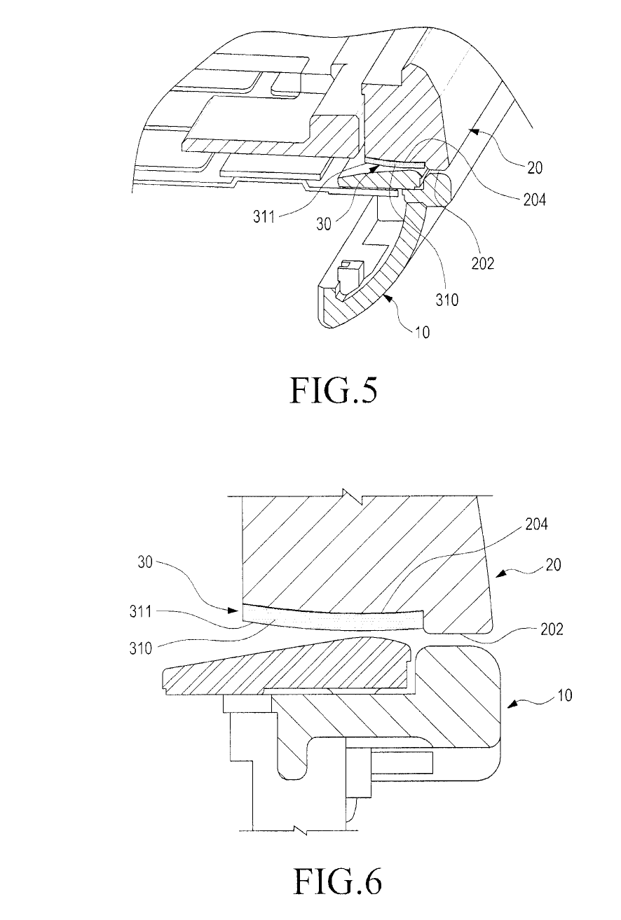

As illustrated in FIGS. 4 and 5, the damping device 30 extends from a bottom surface 202 of the sliding body 20 at a central portion of a front circumference of the sliding body 20 along a circumference of the bottom surface of the sliding body 20 by a predetermined length and protrudes inward (rearward; in the -Y-axis direction). Although frictional interference can be minimized during an opening/closing operation of the sliding body 20 by extending damping devices along a bottom surface of the sliding body 20 at the front circumferences of the body 10 and the sliding body 20, the sliding body 20 may not be smoothly slid. Thus, the damping device 30 preferably has a certain shape at a location where friction (scratching) is most severe. In addition, the damping device 30 is preferably disposed on the bottom surface of the sliding body 20 at an inner portion thereof, considering an external design of the transverse sliding-type terminal.

The damping device 30 includes a groove 204 formed on a bottom surface of the sliding body 20 at a central portion of a front circumference of the sliding body 20 and having a certain thickness and a certain length. The damping device 30 further includes a damper 310 having a frictional surface configured to contact the body 10 and installed in the groove 204. Moreover, since the damping device 30 is installed at a location which cannot be seen by a user from the outside, the presence of the damping device 30 does not pose any limitation on the external design of the transverse sliding-type portable terminal. The damper 310 may be planer or curved so as to have a certain curvature. That is, a frictional surface of the damper 310 is curved to prevent a scratch and provide a smooth feeling/transition during an opening/closing operation of the sliding body 20. Although the damper 310 is curved, the frictional surface 311 of the damper 310 may be preferably curved. Also, the frictional surface 311 of the damper 310 may be rounded or have a certain curvature. In particular, the damper 310 may be convexly curved downward, in which case the frictional surface 311 of the damper 310 is convex downward.

The damper 310 is preferably made of a wear-resistant soft material having a low frictional coefficient, and is a Teflon tape. In particular, the damper 310 is detachably adhered to the groove 204 such that one surface of the damper 310 can be attached on the groove 204 which in turn promotes the assembly efficiency.

As described above, in a damping device for a transverse sliding-type portable terminal according to the present invention, scratching is minimized by reducing friction at an active region vulnerable for scratches during an opening/closing operation of the portable terminal. Further, an appearance of the portable terminal is appealing since the damping device is hidden from a view of a user.

While the invention has been shown and described with reference to certain embodiments thereof, it will be understood by those skilled in the art that various changes in form and details may be made therein without departing from the spirit and scope of the invention as defined by the appended claims.

What is claimed is:

1. A damping device for a transverse sliding-type portable terminal, comprising a body, a sliding body, a sliding guide module configured to transversely guide the sliding of the sliding body in relation to the body,
wherein the damping device is installed at a central portion of a front circumference of the sliding body to minimize friction during an opening/closing operation of the sliding body with respect to the body.

2. The damping device as claimed in claim 1, wherein the damping device includes:
a mounting groove extending along a central bottom surface of a circumference of the sliding body; and
a damper having a frictional surface configured to contact the body and installed in the mounting groove.

3. The damping device as claimed in claim 1, wherein the damping device is mounted onto a bottom surface of the sliding body at the front circumference of the sliding body.

4. The damping device as claimed in claim 3, wherein the damping device extends from a bottom surface of the sliding body at the front circumference of the sliding body and along a circumference of the bottom surface of the sliding body by a predetermined length and protrudes inward.

5. The damping device as claimed in claim 4, wherein the damping device is mounted within the transverse sliding-type portable terminal to be hidden from exterior.

6. The damping device as claimed in claim 2, wherein the damper is made of a wear-resistant soft material and is detachably adhered to the mounting groove.

7. The damping device as claimed in claim 6, wherein the damper is a Teflon tape.

8. The damping device as claimed in claim 2, wherein the frictional surface of the damper is curved so as to be smoothly opened and closed.

9. The damping device as claimed in claim 8, wherein the frictional surface of the damper is rounded or has a predetermined curvature.

10. The damping device as claimed in claim 9, wherein the frictional surface of the damper is convexly curved downward.

11. The damping device as claimed in claim 1, wherein an appearance of the damping device is not exposed to exterior irrespective of an opened/closed state thereof
